(19) United States
(12) Patent Application Publication
(10) Pub. No.: US 2026/0190223 A1
(43) Pub. Date: Jul. 2, 2026

(54) RESIN SHEET, LAMINATE, METAL CLAD LAMINATE, PRINTED WIRING BOARD, AND SEMICONDUCTOR PACKAGE

(71) Applicant: Resonac Corporation, Minato-ku, Tokyo (JP)

(72) Inventors: Yuzuru KOBAYASHI, Minato-ku, Tokyo (JP); Tomohiko KOTAKE, Minato-ku, Tokyo (JP); Shinichiro ABE, Minato-ku, Tokyo (JP); Toshikatsu SHIMAZAKI, Minato-ku, Tokyo (JP)

(21) Appl. No.: 18/859,738

(22) PCT Filed: Apr. 19, 2024
(86) PCT No.: PCT/JP2024/015566

§ 371 Date: Oct. 24, 2024

(30) Foreign Application Priority Data
Apr. 19, 2023 (JP) 2023-068812

(51) Int. Cl. H05K 1/03; B32B 15/06; B32B 25/02; H10W 70/695

(52) U.S. Cl. CPC H05K 1/0373; B32B 15/06; B32B 25/02; H10W 70/695; B32B 2250/02; B32B 2264/101; B32B 2457/08; H05K 2201/0209

(57) ABSTRACT

Provided is a resin sheet which withstands adsorption and transportation by a vacuum adsorption pad for transportation, has low thermal expansion, and has a relative dielectric constant (Dk) of 2.50 to 3.30 in a high frequency band of 10 GHz band or more, and a dielectric dissipation factor (Df) of 0.0020 or less in a high frequency band of 10 GHz band or more. In addition, provided are a laminate, a printed wiring board, and a semiconductor package produced using the resin sheet. The resin sheet is specifically a resin sheet including a resin component (A), and an inorganic filler (B), in which the component (A) contains an elastomer (A1) having a number-average molecular weight of 10,000 or more, a content of the component (B) is 25 to 70 volume % based on a total amount of the resin sheet, and a breaking energy is 0.1 mJ/mm³ or more.

### TECHNICAL FIELD

The present disclosure relates to a resin sheet, a laminate, a metal clad laminate, a printed wiring board, and a semiconductor package.

### BACKGROUND ART

In a mobile communication device represented by a mobile phone, a base station device thereof, a network infrastructure device such as a server or a router, or a large computer, the speed and the capacity of a signal to be used are increasing year by year. Accordingly, a printed wiring board mounted on these electronic devices needs to be compatible with a high frequency, and a substrate material having excellent dielectric characteristics in a high frequency band in which a transmission loss can be reduced, that is, having a small relative dielectric constant (Dk) and a small dielectric dissipation factor (Df) is required.

Meanwhile, with the miniaturization of electronic devices, high-density mounting of electronic components used for a printed wiring board has been advanced. For the high-density mounting, a Pin Grid Array (PGA) type package is used in the related art. The PGA type package has a structure in which a pin protrudes from a rear surface of a substrate in a lattice pattern at regular intervals in a vertical direction. A size of the pin and an interval between the pins are often determined, and it is often difficult to change the design. When the relative dielectric constant of the substrate material decreases, it is necessary to reduce the pin of the PGA type package, and narrow the interval between pins. However, as described above, the relative dielectric constant of the substrate material needs to be kept at a desired value, because it is difficult to make such design changes. In other words, in order to achieve the high-density mounting and high frequency, it is necessary to reduce the dielectric dissipation factor while keeping the relative dielectric constant of the substrate material at a desired value, and development of such a substrate material is desired to a material maker.

So far, as the substrate material that can achieve a low transmission loss, a prepreg using a thermosetting resin composition having excellent dielectric characteristics in a high frequency band has been developed (for example, see PTL 1). The prepreg is formed from an aggregate and a thermosetting resin composition, and the presence of the aggregate makes it possible to handle the prepreg without a support.

### CITATION LIST

### Patent Literature

PTL 1: JP 2020-169276 A

### SUMMARY OF INVENTION

### Technical Problem

Meanwhile, a glass cloth, which is a representative aggregate, is produced by weaving glass strands obtained by bundling and twisting a plurality of glass filaments in the presence of a bundling agent, and normally contains impurities derived from glass components other than SiO₂ (such as B₂O₃, CaO, MgO, and Na₂O) and impurities such as the bundling agent. According to studies by the present inventors, it has been found that there is a limit to respond to a recent high improvement requirement related to the dielectric dissipation factor (Df) because the impurities deteriorate the dielectric characteristics. Therefore, in a prepreg of the related art, a simple resin sheet without using a glass cloth was examined, and as a result, since no aggregate is present, a problem of cutting and crushing of the resin sheet occurred and a low thermal expansion was also impaired, when a support such as a polyethylene terephthalate (PET) film is not attached.

Under such circumstances, the present applicant has already filed an international patent application (PCT/JP2021/038025) for a “resin sheet including a resin component (A) and an inorganic filler (B), in which the component (A) contains an elastomer (A1) having a number-average molecular weight of 10,000 or more, a content of the component (A1) is 30 mass % or more based on the component (A), and a content of the component (B) is 40 to 95 volume % based on a total amount of the resin sheet” to provide a resin sheet capable of handling without a support, having a low thermal expansion, and having a relative dielectric constant (Dk) and a dielectric dissipation factor (Df) in predetermined ranges in a high frequency band of 10 GHz band or more.

However, after further investigations by the present inventors, it was found that, the resin sheet described in the international patent application (PCT/JP2021/038025) can indeed be handled without a support (it is freestanding) and can be transported manually, however, the resin sheet tends to break easily, when a method for transporting the resin sheet by adsorbing it with a vacuum adsorption pad is adopted for implementation on an industrial scale.

In view of the above circumstances, it is an object of the present disclosure to provide a resin sheet withstanding adsorption and transportation by a vacuum adsorption pad for transportation, having low thermal expansion, and having a relative dielectric constant (Dk) of 2.50 to 3.30 in a high frequency band of 10 GHz band or more, and a dielectric dissipation factor (Df) of 0.0020 or less in a high frequency band of 10 GHz band or more. Another object of the present disclosure is to provide a laminate, a printed wiring board, and a semiconductor package produced using the resin sheet.

### Solution to Problem

As a result of studies to achieve the above objects, the present inventors have found that the object can be achieved by the present disclosure.

The present disclosure includes the following embodiments [1] to [13].
[1] A resin sheet including:
a resin component (A); and
an inorganic filler (B),
in which the component (A) contains an elastomer (A1) having a number-average molecular weight of 10,000 or more,
a content of the component (B) is 25 to 70 volume % based on a total amount of the resin sheet, and
a breaking energy is 0.1 mJ/mm³ or more.
[2] The resin sheet according to [1], in which the component (A1) contains one or more kinds selected from the group consisting of a styrene-based elastomer, a maleimide-based elastomer, an olefin-based elastomer, a urethane-based elastomer, a polyester-based elastomer, a polyamide-based elastomer, an acrylic elastomer, a silicone-based elastomer, and a derivative of these elastomers.
[3] The resin sheet according to [1] or [2], further including an elastomer (A2) having a number-average molecular weight of less than 10,000.
[4] The resin sheet according to any one of [1] to [3], in which the component (A) further contains a thermosetting resin (A3).
[5] The resin sheet according to [4], in which the component (A3) contains one or more kinds selected from the group consisting of an epoxy resin, a phenol resin, an unsaturated imide resin, a cyanate resin, an isocyanate resin, a benzoxazine resin, an oxetane resin, an amino resin, an unsaturated polyester resin, an allyl resin, a vinyl benzyl resin, a dicyclopentadiene resin, a silicone resin, a triazine resin, a modified polyphenylene ether resin, and a melamine resin.
[6] The resin sheet according to [4] or [5], in which a total content of the component (A1) and the component (A2) is 40 to 95 mass % based on the component (A).
[7] The resin sheet according to any one of [1] to [6], in which no organic solvent is contained, or when an organic solvent is contained, a content of the organic solvent is less than 1 mass % based on the total amount of the resin sheet.
[8] The resin sheet according to any one of [1] to [7], in which no glass fiber is contained, or when a glass fiber is contained, a content of the glass fiber is 10 volume % or less based on the total amount of the resin sheet.
[9] The resin sheet according to any one of [1] to [8], in which a vacuum degree at which the resin sheet is broken when the resin sheet is adsorbed by a silicone vacuum adsorption pad having a diameter of 20 mm is −15 kPa or less.
[10] A laminate including a cured product of the resin sheet according to any one of [1] to [9].
[11] A metal clad laminate including a metal foil, and a cured product of the resin sheet according to any one of [1] to [9].
[12] A printed wiring board including the laminate according to [10] or the metal clad laminate according to [11].
[13] A semiconductor package including the printed wiring board according to [12], and a semiconductor element.

### Advantageous Effects of Invention

According to the present disclosure, it is possible to provide a resin sheet withstanding adsorption and transportation by a vacuum adsorption pad for transportation, having low thermal expansion, and having a relative dielectric constant (Dk) of 2.50 to 3.30 in a high frequency band of 10 GHz band or more, and a dielectric dissipation factor (Df) of 0.0020 or less in a high frequency band of 10 GHz band or more. In addition, it is possible to provide a laminate, a printed wiring board, and a semiconductor package produced using the resin sheet.

### BRIEF DESCRIPTION OF DRAWINGS

FIG. 1 is a photograph showing a state of a resin sheet when breakage occurs in an adsorption portion of the resin sheet in a measurement of a breaking vacuum degree.

### DESCRIPTION OF EMBODIMENTS

In the numerical range described in the description herein, the upper limit value or the lower limit value of the numerical range may be replaced with a value shown in Examples. In addition, the lower limit value and the upper limit value of the numerical range are arbitrarily combined with the lower limit value or the upper limit value of another numerical range, respectively. In the notation of the numerical range “AA to BB”, the numerical values AA and BB at both ends are included in the numerical range as the lower limit value and the upper limit value, respectively.

In the description herein, for example, the description of “10 or more” means 10 and a numerical value exceeding 10, and the same applies to a case where the numerical value is different. Further, for example, the description of “10 or less” means 10 and a numerical value less than 10, and the same applies to a case where the numerical value is different.

In addition, each component and material exemplified in the description herein may be used alone or in combination of two or more kinds thereof, unless otherwise specified. In the description herein, when a plurality of substances corresponding to each component are present in a composition, the content of each component in the composition means the total amount of the plurality of substances present in the composition, unless otherwise specified.

In the description herein, the term “solid content” refers to a non-volatile content obtained by removing water and a diluent, which will be described later, contained in a photosensitive resin composition, and includes liquid, syrup-like, and wax-like substances at room temperature around 25° C.

In the disclosure herein, a “relative dielectric constant” and a “dielectric dissipation factor” refer to a “relative dielectric constant” and a “dielectric dissipation factor” in a 10 GHz band without particular description. In the disclosure herein, the relative dielectric constant and the dielectric dissipation factor may be collectively referred to as “dielectric characteristics”.

An aspect in which matters described in the description herein are arbitrarily combined is also included in the present disclosure and the present embodiment.

### [Resin Sheet]

One embodiment of the present embodiment is a resin sheet below.

A resin sheet including:
a resin component (A); and
an inorganic filler (B),
in which the component (A) contains an elastomer (A1) having a number-average molecular weight of 10,000 or more,
a content of the component (B) is 25 to 70 volume % based on a total amount of the resin sheet, and
a breaking energy is 0.1 mJ/mm³ or more.

Here, the expression “resin sheet including . . . ” includes both a resin sheet including the components described in “ . . . ” as it is and a resin sheet obtained as at least a portion of the components described in “ . . . ” reacts.

When the breaking energy of the resin sheet of the present embodiment is 0.1 mJ/mm³ or more, the resin sheet can withstand adsorption and transportation by a vacuum adsorption pad for transportation (hereinafter, this characteristic may be referred to as “industrial transportability”). From the same viewpoint, the breaking energy of the resin sheet is preferably 0.5 mJ/mm³ or more, more preferably 1.0 mJ/mm³ or more, and further preferably 1.5 mJ/mm³ or more. When the breaking energy of the resin sheet is 1.0 mJ/mm³ or more, an operation of peeling the resin sheet from a support such as PET tends to be capable using a machine (automation), which is preferable from the viewpoint of industrial implementation.

The upper limit value of the breaking energy of the resin sheet of the present embodiment is not particularly limited, and may be 4.0 mJ/mm³ or less, 3.5 mJ/mm³ or less, 3.0 mJ/mm³ or less, or 2.8 mJ/mm³ or less.

That is, the breaking energy of the resin sheet of the present embodiment may be 0.1 to 4.0 mJ/mm³.

A method for adjusting the breaking energy of the resin sheet of the present embodiment to the above-mentioned range is not particularly limited, and examples thereof include (i) a method for adjusting the content of the component (A1) to be within a range which will be described later, (ii) a method for adjusting the content of the component (B) to be within a range which will be described later, and a combination of the (i) and the (ii).

The resin sheet of the present embodiment is not particularly limited, and from the viewpoint of facilitating adsorption and transportation by a vacuum adsorption pad for transportation, the vacuum degree (hereinafter, may be referred to as a breaking vacuum degree) at which the resin sheet is broken when the resin sheet is adsorbed by the silicone vacuum adsorption pad having a diameter of 20 mm (adsorption portion shape: circular) is preferably −15 kPa or less, more preferably −20 kPa or less, further preferably −30 kPa or less, and particularly preferably −40 kPa or less. Although it is not particularly limited, the vacuum degree may be −150 kPa or more, −120 kPa or more, or −100 kPa or more.

A more detailed method for measuring the breaking vacuum degree is as described in Examples.

The resin sheet of the present embodiment withstands adsorption and transportation by a vacuum adsorption pad for transportation, has low thermal expansion, and has a relative dielectric constant (Dk) of 2.50 to 3.30 in a high frequency band of 10 GHz band or more, and a dielectric dissipation factor (Df) of 0.0020 or less in a high frequency band of 10 GHz band or more.

The relative dielectric constant (Dk) is preferably 2.65 to 3.30, more preferably 2.70 to 3.20, further preferably 2.75 to 3.10, and particularly preferably 2.80 to 3.10.

The dielectric dissipation factor (Df) is preferably 0.0018 or less, more preferably 0.0015 or less, further preferably 0.0010 or less, particularly preferably 0.0009 or less, and most preferably 0.0008 or less. The lower limit value of the dielectric dissipation factor (Df) is not particularly limited, and may be 0.0003 or more, 0.0004 or more, or 0.0005 or more.

The relative dielectric constant (Dk) and the dielectric dissipation factor (Df) are values measured using a split post dielectric resonator (SPDR), and more specifically, a value measured by a method described in Examples.

In addition, one preferable embodiment of the resin sheet of the present embodiment is that no organic solvent is contained, or when an organic solvent is contained, a content of the organic solvent is less than 1 mass % based on the total amount of the resin sheet. Nevertheless, since it has sufficient flexibility, cracks are unlikely to occur, and it has excellent handleability. In one preferable embodiment of the resin sheet of the present embodiment, since the content of the organic solvent is small, there is an advantage that voids are not likely to be generated during reflow.

In one preferred embodiment of the resin sheet of the present embodiment, from the viewpoint of the dielectric dissipation factor (Df), no glass fiber is contained, or when a glass fiber is contained, a content of the glass fiber is 10 volume % or less based on the total amount of the resin sheet (hereinafter, may be referred to as a “feature A”), nevertheless, the resin sheet is excellent in industrial transportability. When the resin sheet contains the glass fiber, the content thereof is preferably 7 volume % or less, more preferably 5 volume % or less, and further preferably 3 volume % or less based on the total amount of the resin sheet, from the viewpoint of the dielectric dissipation factor (Df).

In the description of the feature A in the embodiment, the term “glass fiber” can also be replaced with a “glass cloth” or can also be replaced with a “fiber base material”. That is, in another preferable embodiment of the resin sheet of the present embodiment, from the viewpoint of the dielectric dissipation factor (Df), no glass cloth is contained, or when a glass cloth is contained, a content of the glass cloth is 10 volume % or less based on the total amount of the resin sheet. In addition, in still another preferable embodiment of the resin sheet of the present embodiment, from the viewpoint of the dielectric dissipation factor (Df), no fiber base material is contained, or when a fiber base material is contained, a content of the fiber base material is 10 volume % or less based on the total amount of the resin sheet. When the resin sheet of the present embodiment contains a glass cloth or a fiber base material, the preferable content thereof is the same as in the case of the glass fiber described above.

Hereinafter, the components contained in the resin sheet of the present embodiment will be described in detail.

### (Resin Component (A) and Elastomer (A1) Having Number-Average Molecular Weight of 10,000 or More)

The resin sheet of the present embodiment includes a resin component as the component (A), and the component (A) contains an “elastomer (A1) having a number-average molecular weight of 10,000 or more”.

When the resin sheet of the present embodiment includes the component (A1), the resin sheet can be freestanding even without a support, and shows high flexibility. In addition, the resin sheet of the present embodiment can have the predetermined relative dielectric constant (Dk) and dielectric dissipation factor (Df) by including the component (A1).

From the viewpoint that the resin sheet can be freestanding without a support, the number-average molecular weight (Mn) of the component (A1) is preferably 15,000 or more, more preferably 18,000 or more, further preferably 25,000 or more, particularly preferably 35,000 or more, and most preferably 50,000 or more. The upper limit value of the number-average molecular weight of the component (A1) is not particularly limited, but is preferably 300,000 or less, more preferably 250,000 or less, further preferably 200,000 or less, particularly preferably 120,000 or less, and most preferably 90,000 or less, from the viewpoint of circuit embeddability. That is, the number-average molecular weight (Mn) of the component (A1) is preferably 10,000 or more and 300,000 or less.

In the disclosure herein, the number-average molecular weight is a value measured in terms of standard polystyrene by gel permeation chromatography (GPC) using tetrahydrofuran as a solvent.

The content of the component (A1) is preferably 20 mass % or more, that is, 20 to 100 mass %, more preferably 25 to 90 mass %, further preferably 25 to 80 mass %, particularly preferably 30 to 70 mass %, and most preferably 35 to 65 mass % based on the component (A). When the content of the component (A1) is the lower limit value or more, it is possible to easily control the breaking energy of the resin sheet to the predetermined value and to increase the industrial transportability of the resin sheet, and to have the predetermined relative dielectric constant (Dk) and dielectric dissipation factor (Df).

It is preferable that the component (A1) contains one or more kinds selected from the group consisting of a styrene-based elastomer, a maleimide-based elastomer, an olefin-based elastomer, a urethane-based elastomer, a polyester-based elastomer, a polyamide-based elastomer, an acrylic elastomer, a silicone-based elastomer, and a derivative thereof. Although there are no particular limitations, among these, from the viewpoint of having the predetermined relative dielectric constant (Dk) and dielectric dissipation factor (Df), a styrene-based elastomer and a maleimide-based elastomer are preferable, and a styrene-based elastomer is more preferable. A commercially available product can be used for any elastomer.

Examples of a derivative of the elastomer include those having a reactive functional group in a molecular chain or in a molecular terminal of each elastomer. Examples of the reactive functional group include an acid anhydride group, an epoxy group, a hydroxy group, a carboxy group, an amino group, an amide group, an isocyanate group, an acrylic group, a methacrylic group, and a vinyl group. The derivative of the elastomer may have one reactive functional group or two or more reactive functional groups. In addition, the reactive functional group may be one kind, or two or more kinds thereof.

### (Styrene-Based Elastomer: Component (A1))

The styrene-based elastomer is not particularly limited, and examples thereof include a styrene-butadiene copolymer such as a styrene-butadiene diblock copolymer and a styrene-butadiene-styrene triblock copolymer; a styrene-isoprene copolymer such as a styrene-isoprene diblock copolymer and a styrene-isoprene-styrene triblock copolymer; a hydrogenated product of the styrene-butadiene copolymer; and a hydrogenated product of the styrene-isoprene copolymer. These copolymers may or may not contain structural units derived from a vinyl group-containing aromatic compound such as divinylbenzene.

The styrene-based elastomer may be used alone or in combination of two or more kinds thereof.

The number-average molecular weight (Mn) of the styrene-based elastomer is the same as the number-average molecular weight (Mn) of the component (A1).

A styrene content of the styrene-based elastomer is not particularly limited, and is preferably 10 to 70 mass %, more preferably 10 to 50 mass %, further preferably 10 to 40 mass %, and particularly preferably 15 to 35 mass %. Here, the styrene content is a content of a styrene structural unit with respect to all structural units. When the styrene content is the lower limit value or more, heat resistance tends to be excellent, and when it is the upper limit value or less, rubber elasticity tends to be excellent and the industrial transportability and flexibility tend to be excellent.

The styrene-based elastomer may be unhydrogenated or may be a hydrogenated product. In the case of a hydrogenated product, a hydrogenation rate of the styrene-based elastomer is not particularly limited, and may be preferably 80 to 100 mol %, more preferably 85 to 100 mol %, further preferably 90 to 100 mol %, and may be 95 to 100 mol %.

A commercially available product may be used as the styrene-based elastomer. Examples of commercially available product include TAFTEC (registered trademark) H series, P series, and M series manufactured by Asahi Kasei Corporation; SEPTON (registered trademark) series manufactured by Kuraray Co., Ltd.; and Kraton (registered trademark) G polymer series and D polymer series manufactured by Kraton Polymers Japan Ltd.

### (Maleimide-Based Elastomer: Component (A1))

The maleimide-based elastomer is not particularly limited as long as it is an elastomer having a maleimide skeleton, and examples thereof include a maleimide compound having a structure in which a saturated or unsaturated aliphatic hydrocarbon group is bonded to a maleimide group. The maleimide compound having a structure in which the saturated or unsaturated aliphatic hydrocarbon group is bonded to the maleimide group is preferably a maleimide compound having a structure in which the saturated or unsaturated aliphatic hydrocarbon group is bonded to a nitrogen atom of a maleimide group.

The maleimide compound having a structure in which the saturated or unsaturated aliphatic hydrocarbon group is bonded to the maleimide group preferably has at least two maleimide groups, is more preferably a maleimide compound having one or more structures represented by General Formula (1), and is further preferably a maleimide compound represented by General Formula (2).

In addition, the saturated or unsaturated aliphatic hydrocarbon group preferably has 1 to 100 carbon atoms, more preferably 2 to 50 carbon atoms, and further preferably 4 to 40 carbon atoms. In addition, the saturated or unsaturated aliphatic hydrocarbon group may have 8 to 100 carbon atoms, 8 to 50 carbon atoms, 15 to 50 carbon atoms, 25 to 50 carbon atoms, or 30 to 45 carbon atoms. The saturated or unsaturated aliphatic hydrocarbon group may be either a linear group, a branched group, or a cyclic group, or a combination thereof. The cyclic group is preferably an alicyclic hydrocarbon group. The saturated or unsaturated aliphatic hydrocarbon group is preferably a combination of a linear group and a cyclic group, and more preferably a combination of a linear group and an alicyclic hydrocarbon group.

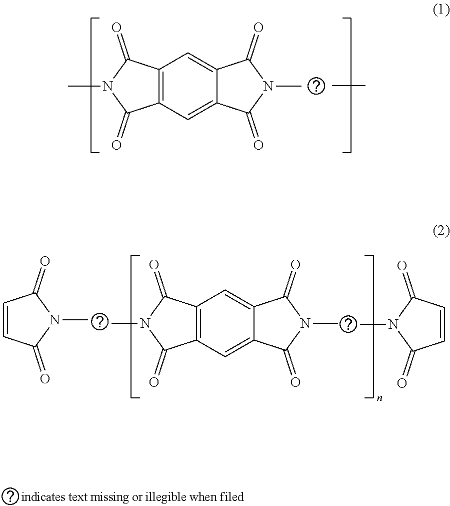

In General Formula (1) and General Formula (2), x represents an integer of 10 to 50, and preferably an integer of 20 to 40. In General Formula (2), n represents the number of structural units surrounded by square parentheses, is preferably an integer of 0 to 50, more preferably an integer of 1 to 30, further preferably an integer of 1 to 20, and particularly preferably an integer of 1 to 10.

Specific examples of the maleimide compound represented by General Formula (2) include compounds represented by Formula (3). In Formula (3), n represents the number of structural units surrounded by parentheses, and represents an integer of 1 to 10.

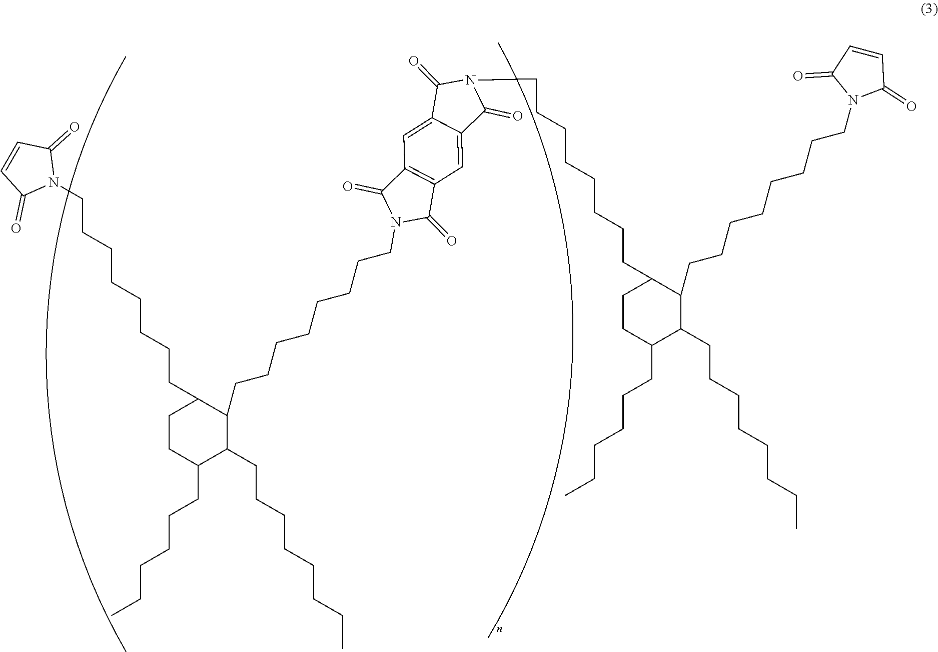

The number-average molecular weight (Mn) of the maleimide-based elastomer is the same as the number-average molecular weight (Mn) of the component (A1), and is preferably 10,000 or more and less than 100,000, may be 10,000 to 50,000, 15,000 to 35,000, or 17,000 to 30,000.

(Elastomer (A2) Having Number-Average Molecular Weight of Less than 10,000)

The component (A) may or may not contain but preferably contains an elastomer other than the “elastomer (A1) having the number-average molecular weight of 10,000 or more”, that is, the “elastomer (A2) having the number-average molecular weight of less than 10,000”. The component (A2) has an effect of increasing compatibility between the component (A1) described above and the “thermosetting resin (A3)” which will be described later.

The number-average molecular weight (Mn) of the component (A2) is preferably 300 or more and less than 10,000, more preferably 400 to 9,000, and may be 500 to 6,000, 1,000 to 5,500, 1,500 to 5,000, 2,000 to 5,000, or 2,500 to 4,000, from the viewpoint of increasing the compatibility between the component (A1) described above and the “thermosetting resin (A3)” which will be described later.

As the component (A2), a material that is the same as the component (A1) is used, however, among these, from the viewpoint of increasing the compatibility between the component (A1) and the “thermosetting resin (A3)” which will be described later, and the viewpoint of the relative dielectric constant (Dk) and the dielectric dissipation factor (Df), the component (A2) is preferably one or more kinds selected from the group consisting of a polybutadiene-based elastomer and a styrene-based elastomer, and may be a polybutadiene-based elastomer, or a styrene-based elastomer.

### (Polybutadiene-Based Elastomer: Component (A2))

Examples of the polybutadiene-based elastomer include polybutadiene diol, polybutadiene dicarboxylic acid, maleated polybutadiene, a butadiene homopolymer, a copolymer copolymerizable with butadiene, a compound obtained by reacting polybutadiene diol with a compound having an isocyanate group, a compound obtained by reacting polybutadiene diol with a compound having a carboxy group, a compound obtained by reacting polybutadiene dicarboxylic acid with a compound having a hydroxy group, and a compound obtained by reacting polybutadiene dicarboxylic acid with a compound having an epoxy group. Among these, a butadiene homopolymer is preferable as the polybutadiene-based elastomer.

The number-average molecular weight (Mn) of the polybutadiene-based elastomer used as the component (A2) is the same as the number-average molecular weight (Mn) of the component (A2).

A commercially available product may be used as the polybutadiene-based elastomer.

Examples of commercially available products of the polybutadiene dicarboxylic acid include C-1000 (content ratio of 1,2-structural unit: 85% or more, manufactured by Nippon Soda Co., Ltd., trade name).

Examples of commercially available product of the butadiene homopolymer include B-1000 (content ratio of 1,2-structural unit: 85%), B-2000 (content ratio of 1,2-structural unit: 85%), B-3000 (content ratio of 1,2-structural unit: 90%) (all of the above, trade name, manufactured by Nippon Soda Co., Ltd.).

Examples of the commercially available product of the compound obtained by reacting the polybutadiene diol with the compound having an isocyanate group include TEAI-1000 and TE-2000 (manufactured by Nippon Soda Co., Ltd., trade name).

Examples of the commercially available product of the compound obtained by reacting the polybutadiene dicarboxylic acid with the compound having an epoxy group include EPB13 (manufactured by Nippon Soda Co., Ltd., trade name).

### (Styrene-Based Elastomer: Component (A2))

The styrene-based elastomer is the same as the styrene-based elastomer in the component (A1). Meanwhile, the number-average molecular weight (Mn) of the styrene-based elastomer used as the component (A2) is the same as the number-average molecular weight (Mn) of the component (A2).

A commercially available product may be used as the styrene-based elastomer.

### (Total Content of Component (A1) and Component (A2))

A total content of the component (A1) and the component (A2) is preferably 40 to 95 mass %, more preferably 45 to 95 mass %, further preferably 50 to 90 mass %, and may be 55 to 90 mass % or 65 to 85 mass % based on the component (A). When the total content of the component (A1) and the component (A2) is the lower limit value or more, a main component of the resin sheet is an elastomer, the dielectric dissipation factor (Df) decreases, and the resin sheet tends to have high flexibility. When the total content of the component (A1) and the component (A2) is the upper limit value or less, the thermosetting resin (A3) which will be described later can be sufficiently contained. Accordingly, various properties such as low thermal expansion, heat resistance, and adhesiveness to a conductor tend to be easily imparted to the resin sheet.

### (Thermosetting Resin (A3))

The component (A) may further contain the thermosetting resin as the component (A3). By containing the thermosetting resin, the heat resistance of the resin sheet can be improved. The component (A3) may be used alone or in combination of two or more kinds thereof.

Examples of the thermosetting resin include an epoxy resin, a phenol resin, an unsaturated imide resin, a cyanate resin, an isocyanate resin, a benzoxazine resin, an oxetane resin, an amino resin, an unsaturated polyester resin, an allyl resin, a vinyl benzyl resin, a dicyclopentadiene resin, a silicone resin, a triazine resin, a modified polyphenylene ether resin, and a melamine resin, and the thermosetting resin preferably contains one or more kinds selected from the group consisting of these. In addition, the thermosetting resin is not particularly limited thereto, and a known thermosetting resin can be used. Among these, an unsaturated imide resin and a vinyl benzyl resin are preferable from the viewpoint of low thermal expansion and heat resistance and the viewpoint of the adhesiveness to a conductor. The modified polyphenylene ether resin is a polyphenylene ether resin having a reactive group such as a vinyl group or a (meth)acryl group.

The unsaturated imide resin is preferably a maleimide compound from the viewpoint of low thermal expansion and heat resistance and the viewpoint of adhesiveness to a conductor. Examples of the maleimide compound include one or more kinds selected from the group consisting of a maleimide compound having one or more N-substituted maleimide groups and a derivative thereof. The maleimide compound herein does not include the maleimide-based elastomer.

The maleimide compound having one or more N-substituted maleimide groups is preferably a maleimide compound having two or more N-substituted maleimide groups. In the maleimide compound having two or more N-substituted maleimide groups, nitrogen atoms contained in two or more maleimide groups are preferably bonded to each other by an organic group.

Examples of a “derivative of the maleimide compound having one or more N-substituted maleimide groups” include an addition reaction product of a maleimide compound having one or more N-substituted maleimide groups and an amine compound such as a diamine compound.

From the viewpoint of the low thermal expansion and heat resistance and the viewpoint of the adhesiveness to a conductor, the maleimide compound is preferably one or more kinds selected from the group consisting of:
a maleimide compound having one or more N-substituted maleimide groups; and
an amino maleimide compound having a structural unit derived from a maleimide compound and a structural unit derived from a diamine compound.

The vinyl benzyl resin is not particularly limited as long as it is a compound having a vinyl benzyl group, and preferably contains one or more kinds selected from the group consisting of a compound having three or more vinyl benzyl groups bonded to an oxygen atom and a compound having one or more vinyl benzyl groups bonded to a carbon atom. In addition, from the viewpoint of the dielectric characteristics, the vinyl benzyl resin is preferably a vinyl benzyl resin containing one or more rings selected from the group consisting of a fluorene ring and an indene ring. The vinyl benzyl group may be any of an o-vinyl benzyl group, an m-vinyl benzyl group or a p-vinyl benzyl group.

When the component (A) further contains the thermosetting resin (A3), the content of the component (A3) is not particularly limited, and is preferably 5 to 60 mass %, more preferably 5 to 55 mass %, further preferably 10 to 50 mass %, and may be 10 to 45 mass %, or 15 to 35 mass % based on the component (A). When the content of the component (A3) is the lower limit value or more, various properties such as low thermal expansion, heat resistance, and adhesiveness to a conductor tend to be easily imparted to the resin sheet. When the content thereof is the upper limit value or less, a main component of the resin sheet is an elastomer, the dielectric dissipation factor (Df) decreases, and the resin sheet tends to have high flexibility.

A total content of the component (A1), the component (A2), and the component (A3) in the component (A) is preferably 50 to 100 mass %, more preferably 80 to 100 mass %, further preferably 90 to 100 mass %, particularly preferably 95 to 100 mass %, and may be 100 mass %.

The content of the component (A) is not particularly limited, and is preferably 80 to 100 mass %, more preferably 85 to 100 mass %, further preferably 90 to 100 mass %, and particularly preferably 95 to 100 mass % based on the total amount of the resin components of the resin sheet.

### (Inorganic Filler (B))

The resin sheet of the present embodiment includes an inorganic filler as the component (B), and the content of the component (B) is 25 to 70 volume % based on the total amount of the resin sheet. By including 25 volume % or more of the component (B), the low thermal expansion is improved and tackiness of the resin sheet is reduced, making it easier to peel the resin sheet from the support. By containing 70 volume % or less of the content of the component (B), the breaking energy of the resin sheet is easily controlled to the predetermined value. The component (B) may be used alone or in combination of two or more kinds thereof.

The inorganic filler is not particularly limited, and examples thereof include silica, alumina, titanium oxide, mica, beryllia, barium titanate, potassium titanate, strontium titanate, calcium titanate, aluminum carbonate, magnesium hydroxide, aluminum hydroxide, aluminum silicate, calcium carbonate, calcium silicate, magnesium silicate, silicon nitride, boron nitride, clay (baked clay or the like), a molybdic acid compound such as zinc molybdate, talc, aluminum borate, and silicon carbide. These may be used alone or in combination of two or more kinds thereof. Among these, silica, alumina, mica, a molybdic acid compound, and talc are preferable, silica and alumina are more preferable, and silica is further preferable from the viewpoint of a coefficient of thermal expansion, elasticity, heat resistance, and flame retardancy. Examples of silica include precipitated silica produced by a wet method and having a high water content, and dry silica produced by a dry method and containing almost no bound water, and examples of dry silica include crushed silica, fumed silica, and fused silica (fused spherical silica) according to a production method.

The shape of the inorganic filler is not particularly limited and may be a spherical shape, a needle shape, a scale shape, and a plate shape, and is preferably a spherical shape from the viewpoint of easily filling the inorganic filler at a high density.

However, in the present embodiment, the inorganic filler (B) does not include a fiber base material such as a glass cloth, and does not include a glass fiber either. Therefore, when the resin sheet of the present embodiment includes a fiber base material such as a glass cloth or a glass fiber, the fiber base material or the glass fiber is included as another component rather than the component (B), a content of each of the fiber base material or the glass fiber is preferably in the range described above (that is, 10 volume % or less, preferably 7 volume % or less, more preferably 5 volume % or less, and further preferably 3 volume % or less based on the total amount of the resin sheet), and a total content of the fiber base material and the glass fiber is preferably 10 volume % or less, more preferably 7 volume % or less, further preferably 5 volume % or less, and particularly preferably 3 volume % or less based on the total amount of the resin sheet.

The inorganic filler may not be surface-treated with a coupling agent, but from the viewpoint of improving the dispersibility in the resin sheet, the inorganic filler may be surface-treated with a coupling agent such as a silane coupling agent, or is preferably surface-treated with a coupling agent such as a silane coupling agent.

Examples of the silane coupling agent include an aminosilane-based coupling agent, an epoxysilane-based coupling agent, a phenylsilane-based coupling agent, an alkylsilane-based coupling agent, an alkenylsilane-based coupling agent, an alkynylsilane-based coupling agent, a haloalkylsilane-based coupling agent, a siloxane-based coupling agent, a hydrosilane-based coupling agent, a silazane-based coupling agent, an alkoxysilane-based coupling agent, a chlorosilane-based coupling agent, a (meth)acrylic silane-based coupling agent, an isocyanurate silane-based coupling agent, a ureido silane-based coupling agent, a mercaptosilane-based coupling agent, a sulfide silane-based coupling agent, and an isocyanate silane-based coupling agent. Among these, an aminosilane-based coupling agent, an alkenylsilane-based coupling agent, and a (meth)acrylic silane-based coupling agent are preferable.

An average particle diameter of the inorganic filler is not particularly limited, and is preferably 0.01 to 20 μm, more preferably 0.1 to 10 μm, further preferably 0.2 to 8 μm, particularly preferably 0.3 to 5 μm, and may be 0.5 to 5 μm, 0.5 to 3 μm, or 0.5 to 1.5 μm.

As the inorganic filler, several kinds of inorganic fillers having different average particle diameters may be used in combination. When several kinds of inorganic fillers having different average particle diameters are used in combination, the resin sheet tends to be easily filled with the inorganic filler at a high density.

Here, in the present disclosure, the average particle diameter is a particle diameter at a point corresponding to 50 volume % when a cumulative frequency distribution curve based on the particle diameter is obtained with the total volume of the particles as 100%. A particle diameter of the inorganic filler can be measured by a particle size distribution measuring device using a laser diffraction scattering method, and the same applies hereinafter.

As described above, the content of the component (B) is 25 to 70 volume %, preferably 30 to 70 volume %, more preferably 35 to 70 volume %, further preferably 45 to 70 volume %, particularly preferably 50 to 70 volume %, and may be 50 to 65 volume % based on the total amount of the resin sheet. When the content of the component (B) is the lower limit value or more, the low thermal expansion is excellent, and the tackiness of the resin sheet is sufficiently decreased. When the content of the component (B) is the upper limit value or less, the industrial transportability is excellent.

As described above, in the present embodiment, since the resin sheet can have the feature A, the resin sheet can also be filled with the component (B) at a high density. In a case of the prepreg, not the resin sheet as in the present embodiment, the content of the inorganic filler is an actual upper limit of 55 volume % based on the total amount of the resin composition in the prepreg, because the prepreg does not have the feature A. When the prepreg contains more than 55 volume % of the inorganic filler, the inorganic filler overflows due to the presence of the fiber base material, making it difficult to melt the resin composition, and as a result, it tends to be impossible to produce the prepreg at all.

### (Organic Filler (C))

The resin sheet of the present embodiment may or may not further include an organic filler as the component (C). When the resin sheet of the present embodiment includes the organic filler, the dielectric dissipation factor (Df) tends to be easily further decreased, and the relative dielectric constant (Dk) tends to be easily adjusted to the predetermined range.

The organic filler is not particularly limited, and examples thereof include resin particles having a single structure formed of polyethylene, polypropylene, polystyrene, a polyphenylene ether resin, a silicone resin, or a tetrafluoroethylene resin; and resin particles having a core-shell structure including a core layer in a rubber state formed of an acrylic acid ester-based resin, a methacrylic acid ester-based resin, or a conjugated diene-based resin, and a shell layer in a glass state formed of an acrylic acid ester-based resin, a methacrylic acid ester-based resin, an aromatic vinyl-based resin, or a vinyl cyanide-based resin.

The average particle diameter of the organic filler is preferably 0.1 to 10 μm, more preferably 0.2 to 5 μm, further preferably 0.5 to 4.0 μm, and particularly preferably 1.5 to 4.0 μm.

When the resin sheet of the present embodiment includes the organic filler (C), the content thereof is not particularly limited, and is preferably 1 to 30 volume %, more preferably 3 to 25 volume %, and further preferably 5 to 20 volume % based on the total amount of the resin sheet.

### (Thermal Polymerization Initiator (D))

The resin sheet of the present embodiment may further include a thermal polymerization initiator as the component (D).

The thermal polymerization initiator is not particularly limited, and examples thereof include a hydroperoxide-based compound such as diisopropylbenzene hydroperoxide “PERCUMYL P” (trade name, manufactured by NOF Corporation (the same applies hereinafter)), cumene hydroperoxide “PERCUMYL H”, and t-butyl hydroperoxide “PERBUTYL H”; a dialkyl peroxide-based compound such as α,α-bis(t-butyl peroxy-m-isopropyl)benzene “PERBUTYL P”, dicumyl peroxide “PERCUMYL D”, 2,5-dimethyl-2,5-bis(t-butyl peroxy) hexane “PERHEXA 25B”, t-butyl cumyl peroxide “PERBUTYL C”, di-t-butyl-peroxide “PERBUTYL D”, 2,5-dimethyl-2,5-bis(t-butyl peroxy) hexyne-3 “PERHEXYNE 25B”, and t-butylperoxy-2-ethylhexanoate “PERBUTYL O”; a ketone peroxide-based compound; a peroxyketal-based compound such as n-butyl 4,4-di-(t-butylperoxy) valerate “PERHEXA V”; a diacyl peroxide-based compound; a peroxydicarbonate-based compound; an organic peroxide such as a peroxyester compound; and an azo compound such as 2,2′-azobisisobutyronitrile, 2,2′-azobis(2-cyclopropylpropionitrile), and 2,2′-azobis(2,4-dimethylvaleronitrile). Among these, α,α-bis(t-butyl peroxy-m-isopropyl)benzene “PERBUTYL P” is preferable.

When the resin sheet of the present embodiment includes the thermal polymerization initiator (D), the content thereof is not particularly limited, and is preferably 0.01 to 5 mass %, more preferably 0.1 to 4 mass %, and further preferably 0.5 to 3 mass % based on the component (A). When the content of the thermal polymerization initiator (D) is the lower limit value or more, a sufficiently thermally cured resin sheet tends to be easily obtained, and when the content thereof is the upper limit value or less, heat resistance tends to be excellent.

### (Other Components)

The resin sheet of the present embodiment may further include other components. The other components are not particularly limited, and examples thereof include a curing accelerator, a flame retardant, a flame-retardant auxiliary, a peroxide, an antioxidant, a fluorescent whitening agent, an adhesion improver, a thermal stabilizer, an antistatic agent, an ultraviolet absorbent, a pigment, a colorant, and a lubricant.

When the resin sheet of the present embodiment includes the other components, the content thereof for one kind is preferably 5 mass % or less, more preferably 3 mass % or less, further preferably 1 mass % or less, and may be 0.1 mass % or more or 0.5 mass % or more based on the total amount of the resin sheet.

### (Thickness of Resin Sheet)

A thickness of the resin sheet of the present embodiment is preferably equivalent to a thickness of one prepreg used for a printed wiring board of the related art, and is preferably 10 to 120 μm, more preferably 20 to 110 μm, further preferably 20 to 100 μm, and may be 40 to 100 μm, or 60 to 100 μm. However, the thickness of the resin sheet of the present embodiment is not limited to the above-mentioned range.

### (Method for Producing Resin Sheet)

The resin sheet of the present embodiment can be produced by, for example, applying a resin composition obtained by mixing the respective components and an organic solvent as necessary, to a support, heating and drying the resin composition to form a B-stage, and then peeling the support. Here, in the description herein, B-staging is to bring into a B-stage state as defined in JIS K6900 (1994), and is also referred to as semi-curing.

Examples of the support include a film of polyolefin such as polyethylene, polypropylene, and polyvinyl chloride; a film of polyester such as polyethylene terephthalate (hereinafter, also referred to as “PET”) and polyethylene naphthalate; various plastic films such as a polycarbonate film and a polyimide film; a metal foil such as a copper foil and an aluminum foil; and release paper. The support may be surface-treated by a mat treatment, a corona treatment, or the like. In addition, the support may be release-treated with a silicone resin-based releasing agent, an alkyd resin-based releasing agent, a fluororesin-based releasing agent, or the like.

The thickness of the support is not particularly limited, and is preferably 10 to 150 μm, and more preferably 25 to 80 μm.

A method for applying the resin composition to the support is not particularly limited, and the resin composition can be applied using a coating device known by those skilled in the art, such as a comma coater, a bar coater, a kiss coater, a roll coater, a gravure coater, and a die coater. These coating devices may be appropriately selected according to the thickness of the resin sheet to be produced.

A drying temperature and a drying time after the coating of the resin composition are not particularly limited, and for example, a method for drying at 50 to 140° C. for about 3 to 15 minutes is used. The drying temperature is preferably 70 to 135° C., and more preferably 80 to 130° C. The drying time is preferably 3 to 12 minutes.

In the resin sheet of the present embodiment, a protective film may be provided on one surface or both surfaces. By providing the protective film, it is possible to prevent damage during transportation. In addition, the resin sheet of the present embodiment may not be provided with a protective film.

### [Laminate and Metal Clad Laminate]

The laminate of the present embodiment is a laminate including a cured product of the resin sheet of the present embodiment. A laminate having a metal foil may also be referred to as a metal clad laminate, that is, the metal clad laminate of the present embodiment is a metal clad laminate including a metal foil, and a cured product of the resin sheet of the present embodiment.

The metal clad laminate of the present embodiment can be produced by, for example, disposing a metal foil on one surface or both surfaces of one resin sheet of the present embodiment, or disposing a metal foil on one surface or both surfaces of a laminated sheet obtained by stacking two or more (preferably 2 to 20 and more preferably 2 to 10) resin sheets of the present embodiment, and then performing heat and press forming.

As another method for producing the metal clad laminate of the present embodiment, a method for disposing one or more resin films other than the present embodiment on one surface or both surfaces of one resin sheet of the present embodiment, disposing a metal foil, and performing heating and pressing is used. In this case, when two or more resin films other than the present embodiment are used, the resin films may be the same resin film or may be a combination of different resin films. The same resin film refers to resin films having the same components, and the different resin films refer to resin films having different components, and the same applies hereinafter. Here, as the resin film other than the present embodiment, a known resin film with a support used for multilayer formation of a printed wiring board can be used, and the same applies hereinafter.

As still another method for producing the metal clad laminate of the present embodiment, a method for disposing one or more resin films other than the present embodiment on one surface or both surfaces of a laminated sheet obtained by stacking two or more (preferably 2 to 20 and more preferably 2 to 10) resin sheets of the present embodiment, disposing a metal foil, and performing heating and pressing is used. In this case, when two or more resin films other than the present embodiment are used, the resin films may be the same resin film or a combination of different resin films.

The metal of the metal foil is not particularly limited as long as it is used for an electrical insulating material, but from the viewpoint of conductivity, the metal may be copper, gold, silver, nickel, platinum, molybdenum, ruthenium, aluminum, tungsten, iron, titanium, chromium, or an alloy containing one or more of these metal elements, and is preferably copper or aluminum, and more preferably copper.

The conditions for the heat and press forming are not particularly limited, and for example, the heat and press forming can be performed under conditions of a temperature of preferably 100 to 300° C., more preferably 150 to 250° C., and further preferably 180 to 240° C., a pressure of preferably 0.2 to 10 MPa and more preferably 1.5 to 6 MPa, and a time of preferably 0.1 to 5 hours and more preferably 1 to 3 hours. In addition, for the heat and press forming, a method for holding the vacuum state preferably for 0.5 to 5 hours using a vacuum press can be adopted.

In the laminate and the metal clad laminate of the present embodiment, the resin sheet is C-staged to obtain a cured product. That is, the laminate of the present embodiment includes a C-staged resin sheet, and the metal clad laminate of the present embodiment can also be said to include the C-staged resin sheet and the metal foil.

Here, in the description herein, C-staging is to bring into a C-stage state as defined in JIS K6900 (1994).

### [Printed Wiring Board]

The printed wiring board of the present embodiment includes the laminate or the metal clad laminate of the present embodiment. Here, the expression “including the laminate or the metal clad laminate” includes a case where the laminate or the metal clad laminate is included as it is, and a case where the laminate or the metal clad laminate is subjected to, for example, circuit forming processing by drilling, metal plating, etching of a metal foil, or the like.

The printed wiring board of the present embodiment can be produced by using the laminate of the present embodiment where the metal foil is provided on one surface or both surfaces, that is, the metal clad laminate, by performing circuit forming processing by drilling, metal plating, etching of a metal foil, or the like by a known method, and further performing multilayer processing, as necessary.

### [Semiconductor Package]

The semiconductor package of the present embodiment is a semiconductor package including the printed wiring board of the present embodiment and a semiconductor element. The semiconductor package of the present embodiment can be produced by mounting a semiconductor element such as a semiconductor chip or a memory on a predetermined position of the printed wiring board of the present embodiment and sealing the semiconductor element with a sealing resin.

The resin sheet, the laminate, the printed wiring board, and the semiconductor package of the present embodiment can be suitably used in an electronic device that handles a high-frequency signal of 10 GHz or more. In particular, the printed wiring board is useful as a printed wiring board for millimeter-wave radar.

Although preferred embodiments have been described above, these are examples for describing the present disclosure, and the scope of the present disclosure is not limited to these embodiments. The present disclosure also includes various embodiments different from the embodiment without departing from the gist of the present disclosure.

### EXAMPLES

Hereinafter, the present embodiment will be specifically described with reference to Examples. However, the present embodiment is not limited to the following examples.

### Production Example 1; Production of Vinyl Benzyl Resin

Into a reaction vessel having a volume of 500 mL equipped with a stirring device, a thermometer, a reflux tube, and a nitrogen inlet, 35.6 parts by mass of indene, 101.2 parts by mass of chloromethylstyrene (a mixture of 50 mass % of m-body and 50 mass % of p-body), 7.1 parts by mass of tetra-n-butylammonium bromide (phase-transfer catalyst), 0.1 parts by mass of phenothiazine (polymerization inhibitor), and 77.6 parts by mass of toluene (solvent) were charged, and heated and stirred at 40° C. while blowing nitrogen at a flow rate of 50 ml/min.

Next, 46.5 parts by mass of a sodium hydroxide aqueous solution having a concentration of 48 mass % was added dropwise over 20 minutes, followed by stirring at 60° C. for 9 hours. During a reaction, the blowing of nitrogen was continued. A reaction product was cooled to room temperature (25° C.), neutralized with a 10% hydrochloric acid aqueous solution, and then washed with pure water twice, toluene was distilled off under reduced pressure, and the obtained viscous liquid was then washed with methanol and then dried in a vacuum, thereby obtaining a vinyl benzyl resin A3-1.

It was confirmed by 1H-NMR analysis that the vinyl benzyl resin A3-1 had a structure in which two hydrogen atoms directly bonded to the carbon atom at the first position of indene represented by Formula (A3-1) were substantially all substituted with vinyl benzyl groups. In addition, GPC analysis showed that the vinyl benzyl resin A3-1 was a mixture of a compound into which two vinyl benzyl groups had been introduced and a compound into which three vinyl benzyl groups had been introduced.

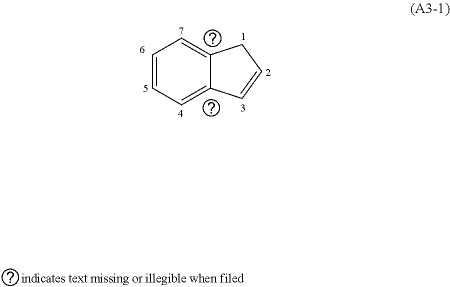

### Examples 1 to 10 and Comparative Examples 1 to 4

### (Production of Resin Sheet)

Each component shown in Table 1 or 2 was stirred and mixed with toluene at room temperature (25° C.) according to the blending amount shown in Table 1 or 2 to prepare a resin composition having a solid content concentration of 60 mass %.

The prepared resin composition was applied to a PET film having a thickness of 50 μm (manufactured by Toyobo Co., Ltd., trade name: Purex (registered trademark) A5300), and then heated and dried at 110° C. for 5 minutes to bring the resin composition to the B-stage. As a result, a resin sheet with a PET film (width 500 mm× length 500 mm, thickness: 80 μm) was obtained. For the resin sheet with a PET film, a corner of the PET film was gripped with tweezers, and the PET film was slowly peeled off from the resin sheet toward the other diagonal corner to obtain a bare resin sheet.

### (Production of Copper Clad Laminate)

Four or ten resin sheets obtained by the above method were stacked to form a laminated sheet. A low-profile copper foil (manufactured by Mitsui Mining & Smelting Co., Ltd., trade name: SI VSP AM 3R) having a thickness of 18 μm was disposed above and below the laminated sheet in a state in which an M surface (mat surface) thereof was in contact with the laminated sheet, and the resin sheet was C-staged by heat and press forming under the conditions of a temperature of 230° C., a pressure of 2 MPa, and a time of 120 minutes, thereby producing a double-sided copper clad laminate (a double-sided copper clad laminate using four resin sheets is referred to as a “double-sided copper clad laminate A”, and a double-sided copper clad laminate using ten resin sheets is referred to as a “double-sided copper clad laminate B”).

### [Evaluation and Measurement Method]

Using the resin sheets or the copper clad laminates obtained in Examples and Comparative Examples, each measurement and evaluation were performed according to the following methods. The results are shown in Table 1 and Table 2.

### (1. Evaluation of Industrial Transportability)

In each example, the resin sheet peeled off from the PET film was adsorbed by a vacuum adsorption pad using an adsorption device including the vacuum adsorption pad (diameter: 20 mm, formed of silicone), and was then transported 500 mm in a lateral direction. The vacuum degree during transportation and adsorption was-27 kPa. The state at that time was evaluated according to the following evaluation criteria and used as an indicator of industrial transportability.

Evaluation A indicates excellent industrial transportability, Evaluation B indicates that the resin sheet is freestanding even without a support, and industrial transportability is insufficient, and Evaluation C indicates that the resin sheet is not freestanding.
A: The resin sheet was not broken even after being transported with a vacuum adsorption pad.
B: When the resin sheet was adsorbed by a vacuum adsorption pad, or being transported, the resin sheet was broken.
C: The resin sheet was broken when the PET film was peeled.

### (2. Measurement of Breaking Energy)

In each example, five evaluation resin sheets (width 10 mm×length 40 mm) were prepared from the resin sheet peeled off from the PET film, and a tensile test was performed in a length direction using an autograph (manufactured by Shimadzu Corporation, AG-X). Each evaluation resin sheet was measured under conditions of a measurement temperature of 25° C., a distance between chucks of 20 mm, and a tensile speed of 10 mm/min.

The breaking energy was calculated by integrating stress from an origin of elongation (an initial distance between chucks) to a breaking point of each test piece (a displacement amount when a test piece was broken) by displacement. The obtained breaking energy was divided by a volume of the test piece to obtain the breaking energy per unit volume (mJ/mm³). An average value of five measurements was defined as the breaking energy of the resin sheet.

### (3. Measurement of Breaking Vacuum Degree)

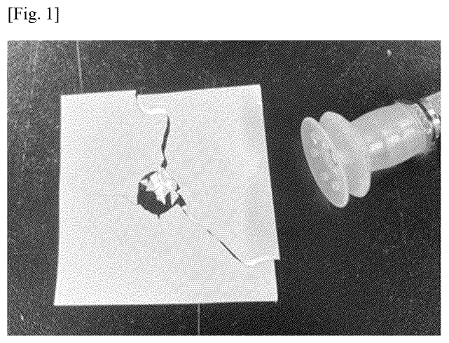

In each example, the resin sheet peeled off from the PET film was adsorbed for 3 seconds by a vacuum adsorption pad after setting an arbitrary vacuum degree using an adsorption device including the vacuum adsorption pad (diameter: 20 mm, formed of silicone), and was then released to normal pressure, and the breaking of the sheet was visually confirmed. When the sheet was not broken, the same operation was performed at a position different from the previous position after resetting the vacuum degree higher. The vacuum degree at the time when the adsorption portion of the resin sheet was broken (see FIG. 1) was defined as the breaking vacuum degree.

It is preferable that the breaking vacuum degree is −15 kPa or less (preferably −20 kPa or less, more preferably −30 kPa or less, and further preferably −40 kPa or less), because adsorption and transportation are easily performed by a vacuum adsorption pad for transportation.

### (4. Dielectric Characteristics: Measurement of Relative Dielectric Constant and Dielectric Dissipation Factor)

An evaluation substrate of 40 mm×50 mm was produced from an evaluation substrate obtained by removing the copper foil by immersing the double-sided copper clad laminate A obtained in each example in a 10 mass % solution of ammonium persulfate (manufactured by Mitsubishi Gas Chemical Company, Ltd.) which is a copper etching solution.

Using the evaluation substrate, the relative dielectric constant and the dielectric dissipation factor were measured at 25° C. in a 10 GHz band using a “PNA Network Analyzer N5227A” (manufactured by Agilent Technologies) provided with a split post dielectric resonator (SPDR).

### (5. Measurement of Coefficient of Thermal Expansion)

A 5 mm square evaluation substrate was produced by removing the copper foil by immersing the double-sided copper clad laminate B obtained in each example in a copper etching solution, and thermomechanical analysis was performed by a compression method using a thermomechanical measurement apparatus (TMA) [manufactured by TA Instruments Japan INC., Q400 (model number)].

After the evaluation substrate was mounted on the apparatus in an X direction, the coefficient of thermal expansion was continuously measured twice under measurement conditions of a load of 5 g and a rate of temperature rise of 10° C./min. An average coefficient of thermal expansion (average of coefficients of linear thermal expansion in plane direction) from 50° C. to 120° C. in the second measurement was calculated, and this was set as the coefficient of thermal expansion (coefficient of linear thermal expansion). The second measurement result was used in order to improve the accuracy.

### (6. Measurement of Glass Transition Temperature (Tg))

Using a 5 mm square test piece obtained by removing the copper foil by immersing the double-sided copper clad laminate B obtained in each example in a copper etching solution, a glass transition temperature was measured by a thermomechanical measurement apparatus (TMA) [manufactured by TA Instruments Japan INC., Q400 (model number)] based on IPC (The Institute for Interconnecting and Packaging Electronic Circuits) standard.

As the glass transition temperature is high, the heat resistance is excellent.

TABLE 1

| | | | | | Example | | | | |
|---|---|---|---|---|---|---|---|---|---|
| Composition | | | | Unit | 1 | 2 | 3 | 4 | 5 |
| Component | | Elastomer (A1) | Elastomer 1 | Parts by | 30 | 30 | 30 | 30 | 40 |
| (A) | | having Mn of | (Mn = 70,000) | mass | | | | | |
| | | 10,000 or more | | | | | | | |
| | | Elastomer (A2) | Elastomer 2 | Parts by | | | | | |
| | | having Mn of | (Mn = 1,200) | mass | | | | | |
| | | less than 10,000 | Elastomer 3 | Parts by | 20 | 20 | 20 | 20 | 20 |
| | | | (Mn = 3,200) | mass | | | | | |
| | | Thermosetting | Vinyl benzyl | Parts by | | | | | 20 |
| | | resin (A3) | resin | mass | | | | | |
| | | | Unsaturated | Parts by | 50 | 50 | 50 | 50 | 20 |
| | | | imide resin | mass | | | | | |
| Component | | Inorganic filler | Silica | Volume % | 30 | 40 | 50 | 60 | 50 |
| (B) | | | | | | | | | |
| Component | | Thermal | Thermal | Parts by | 2 | 2 | 2 | 2 | 2 |
| (D) | | polymerization | polymerization | mass | | | | | |
| | | initiator | initiator 1 | | | | | | |
| Other | | Flame retardant | Flame retardant 1 | Parts by | | | | | 3 |
| components | | | | mass*¹ | | | | | |
| Evaluation | Resin | Industrial transportability | | — | A | A | A | A | A |
| result | sheet | Breaking energy | | mJ/mm³ | 1.92 | 2.76 | 1.6 | 0.65 | 0.14 |
| | | Breaking vacuum degree | | kPa | −88 | −94 | −85 | −68 | −40 |
| | Laminate | Dielectric | Relative dielectric | — | 2.80 | 2.80 | 2.90 | 3.00 | 2.89 |
| | | characteristics | constant (Dk)/10 GHz | | | | | | |
| | | | Dielectric dissipation | — | 0.0017 | 0.0019 | 0.0017 | 0.0014 | 0.0008 |
| | | | factor (Df)/10 GHz | | | | | | |
| | | Coefficient of thermal expansion | | ppm/° C. | 46 | 26.6 | 33.8 | 23.3 | 30 |
| | | Glass transition temperature | | ° C. | 253 | 257 | 272 | 247 | 200 |
| | | | | | Example | | | | |
| Composition | | | | Unit | 6 | 7 | 8 | 9 | 10 |
| Component | | Elastomer (A1) | Elastomer 1 | Parts by | 50 | 60 | 60 | 50 | 50 |
| (A) | | having Mn of | (Mn = 70,000) | mass | | | | | |
| | | 10,000 or more | | | | | | | |
| | | Elastomer (A2) | Elastomer 2 | Parts by | | | | | |
| | | having Mn of | (Mn = 1,200) | mass | | | | | |
| | | less than 10,000 | Elastomer 3 | Parts by | 20 | 20 | 20 | 30 | 30 |
| | | | (Mn = 3,200) | mass | | | | | |
| | | Thermosetting | Vinyl benzyl | Parts by | 10 | | | 20 | |
| | | resin (A3) | resin | mass | | | | | |
| | | | Unsaturated | Parts by | 20 | 20 | 20 | | 20 |
| | | | imide resin | mass | | | | | |
| Component | | Inorganic filler | Silica | Volume % | 50 | 50 | 67 | 60 | 60 |
| (B) | | | | | | | | | |
| Component | | Thermal | Thermal | Parts by | 2 | 2 | 2 | 2 | 2 |
| (D) | | polymerization | polymerization | mass | | | | | |
| | | initiator | initiator 1 | | | | | | |
| Other | | Flame retardant | Flame retardant 1 | Parts by | 3 | 3 | | | |
| components | | | | mass*¹ | | | | | |
| Evaluation | Resin | Industrial transportability | | — | A | A | A | A | A |
| result | sheet | Breaking energy | | mJ/mm³ | 0.68 | 1.72 | 0.21 | 1.62 | 1.6 |
| | | Breaking vacuum degree | | kPa | −75 | −86 | −30 | −80 | −82 |
| | Laminate | Dielectric | Relative dielectric | — | 2.87 | 2.86 | 2.93 | 2.89 | 2.95 |
| | | characteristics | constant (Dk)/10 GHz | | | | | | |
| | | | Dielectric dissipation | — | 0.0007 | 0.0006 | 0.0006 | 0.0008 | 0.0009 |
| | | | factor (Df)/10 GHz | | | | | | |

| | | | | | | |
|---|---|---|---|---|---|---|
| Coefficient of thermal expansion | ppm/° C. | 58 | 85 | 14 | 24 | 30 |
| Glass transition temperature | ° C. | 203 | 227 | 198 | 213 | 208 |

*¹Amount of phosphorus atom equivalent to 100 parts by mass of component (A)

TABLE 2

| | | | | | Comparative Example | | | |
|---|---|---|---|---|---|---|---|---|
| Composition | | | | Unit | 1 | 2 | 3 | 4 |
| Component | | Elastomer (A1) | Elastomer 1 | Parts by | | | 5 | 50 |
| (A) | | having Mn of | (Mn = 70,000) | mass | | | | |
| | | 10,000 or more | | | | | | |
| | | Elastomer (A2) | Elastomer 2 | Parts by | 100 | | | 20 |
| | | having Mn of | (Mn = 1,200) | mass | | | | |
| | | less than 10,000 | Elastomer 3 | Parts by | | 100 | 95 | |
| | | | (Mn = 3,200) | mass | | | | |
| | | Thermosetting | Vinyl benzyl | Parts by | | | | |
| | | resin (A3) | resin | mass | | | | |
| | | | Unsaturated | Parts by | | | | 30 |
| | | | imide resin | mass | | | | |
| Component | | Inorganic filler | Silica | Volume % | 70 | 70 | 70 | 72 |
| (B) | | | | | | | | |
| Component | | Thermal | Thermal | Parts by | 2 | 2 | 2 | 2 |
| (D) | | polymerization | polymerization | mass | | | | |
| | | initiator | initiator 1 | | | | | |
| Other | | Flame retardant | Flame retardant 1 | Parts by | | | | |
| components | | | | mass*¹ | | | | |
| Evaluation | Resin | Industrial transportability | | — | C | C | C | B |
| result | sheet | Breaking energy | | mJ/mm³ | 0 | 0 | 0 | 0.05 |
| | | Breaking vacuum degree | | kPa | | | | −12 |
| | Laminate | Dielectric | Relative dielectric | — | | | | 3.15 |
| | | characteristics | constant (Dk)/10 GHz | | | | | |
| | | | Dielectric dissipation | — | | | | 0.0008 |
| | | | factor (Df)/10 GHz | | | | | |

| | | |
|---|---|---|
| Coefficient of thermal expansion | ppm/° C. | 16 |
| Glass transition temperature | ° C. | 221 |

*¹Amount of phosphorus atom equivalent to 100 parts by mass of component (A)

The components shown in Table 1 or Table 2 are as follows.

### [Component (A)]

### (Component (A1))

Elastomer 1: styrene-ethylene-butylene-styrene copolymer (SEBS), styrene content: 20 mass %, hydrogenation ratio: 100 mol %, Mn=70,000

### (Component (A2))

Elastomer 2:1,2-polybutadiene homopolymer, Mn=1,200
Elastomer 3:1,2-polybutadiene homopolymer, Mn=3,200

### (Component (A3))

Vinyl benzyl resin: Vinyl benzyl resin A3-1 obtained by Production Example 1
Unsaturated imide resin: aromatic bismaleimide compound having the following structure and containing an indane ring

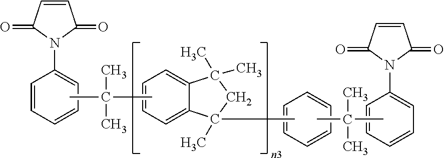

(In the above formula, n3 is the number of 0.95 to 10.0.)

### [Component (B)]

Silica: silica having an average particle diameter of 1.0 μm treated with an aminosilane-based coupling agent

### [Component (D)]

Thermal polymerization initiator 1: α,α-bis(t-butyl peroxy-m-isopropyl)benzene (see the following structure)

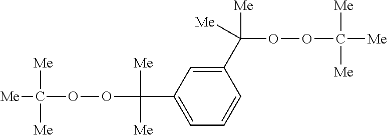 [SMILES: CC(C)(C)OOC(C)(C)c1cccc(C(C)(C)OOC(C)(C)C)c1]

### [Other Components]

Flame Retardant 1:1,3-phenylene bis(di-2,6-xylenyl phosphate), phosphorus content: 9 mass %

The number-average molecular weight of the component (A) was measured by the following method.

### (Method for Measuring Number-Average Molecular Weight (Mn))

The number-average molecular weight was converted from a calibration curve using standard polystyrene by gel permeation chromatography (GPC). The calibration curve was approximated by a cubic equation using standard polystyrene: TSK standard POLYSTYRENE (Type; A-2500, A-5000, F-1, F-2, F-4, F-10, F-20, F-40) [manufactured by Tosoh Corporation, trade name]. The GPC measurement conditions are shown below.

### [GPC Measurement Conditions]

Apparatus: High-speed GPC apparatus HLC-8320GPC
Detector: Ultraviolet absorption detector UV-8320 [manufactured by Tosoh Corporation]
Column: Guard column; TSK Guardcolumn SuperHZ-L+Column: TSKgel SuperHZM-N+TSKgel SuperHZM-M+TSKgel SuperH-RC (all manufactured by Tosoh Corporation, trade name)

$$Column size : 4.6 \times 20 mm ( guard column ) , 4.6 \times 150 mm ( column ) ,$$

$$6. \times 150 mm$$

### (Reference Column)

Eluent: tetrahydrofuran
Sample concentration: 10 mg/5 ml
Injection volume: 25 μL
Flow rate: 1.00 mL/min
Measurement temperature: 25° C.

As apparent from the results shown in Tables 1 and 2, the resin sheet produced in Examples satisfies (1) withstanding adsorption and transportation by a vacuum adsorption pad for transportation, (2) low thermal expansion, (3) a relative dielectric constant (Dk) in a range of 2.50 to 3.30 in a high frequency band of 10 GHz band or more, and (4) a dielectric dissipation factor (Df) of 0.0020 or less in a high frequency band of 10 GHz band or more. In addition, it is found that the resin sheet produced in Examples has the breaking vacuum degree of −15 kPa or less, the adsorption and transportation is easily performed by a vacuum adsorption pad for transportation, and excellent heat resistance is also obtained.

On the other hand, the resin sheets of Comparative Examples 1 to 3 in which the breaking energy was less than 0.1 mJ/mm³ did not stand by themselves, and the industrial transportability was very poor. In addition, even in Comparative Example 4 in which the resin sheet was easily freestanding by increasing the content of the component (A1), the content of the silica was as high as 72 mass %, and thus the breaking energy was small and the industrial transportability was insufficient.

1. A resin sheet comprising:
a resin component (A); and
an inorganic filler (B),
wherein the component (A) contains an elastomer (A1) having a number-average molecular weight of 10,000 or more,
a content of the component (B) is 25 to 70 volume % based on a total amount of the resin sheet, and
a breaking energy is 0.1 mJ/mm³ or more.

2. The resin sheet according to claim 1,
wherein the component (A1) contains one or more kinds selected from the group consisting of a styrene-based elastomer, a maleimide-based elastomer, an olefin-based elastomer, a urethane-based elastomer, a polyester-based elastomer, a polyamide-based elastomer, an acrylic elastomer, a silicone-based elastomer, and a derivative of these elastomers.

3. The resin sheet according to claim 1, further comprising:
an elastomer (A2) having a number-average molecular weight of less than 10,000.

4. The resin sheet according to claim 1,
wherein the component (A) further contains a thermosetting resin (A3).

5. The resin sheet according to claim 4,
wherein the component (A3) contains one or more kinds selected from the group consisting of an epoxy resin, a phenol resin, an unsaturated imide resin, a cyanate resin, an isocyanate resin, a benzoxazine resin, an oxetane resin, an amino resin, an unsaturated polyester resin, an allyl resin, a vinyl benzyl resin, a dicyclopentadiene resin, a silicone resin, a triazine resin, a modified polyphenylene ether resin, and a melamine resin.

6. The resin sheet according to claim 4,
wherein a total content of the component (A1) and the component (A2) is 40 to 95 mass % based on the component (A).

7. The resin sheet according to claim 1,
wherein no organic solvent is contained, or when an organic solvent is contained, a content of the organic solvent is less than 1 mass % based on the total amount of the resin sheet.

8. The resin sheet according to claim 1,
wherein no glass fiber is contained, or when a glass fiber is contained, a content of the glass fiber is 10 volume % or less based on the total amount of the resin sheet.

9. The resin sheet according to claim 1,
wherein a vacuum degree at which the resin sheet is broken when the resin sheet is adsorbed by a silicone vacuum adsorption pad having a diameter of 20 mm is −15 kPa or less.

10. A laminate comprising:
a cured product of the resin sheet according to claim 1.

11. A metal clad laminate comprising:
a metal foil; and
a cured product of the resin sheet according to claim 1.

12. A printed wiring board comprising:
the laminate according to claim 10.

13. A semiconductor package comprising:
the printed wiring board according to claim 12; and
a semiconductor element.
